(19) United States
(12) Patent Application Publication
(10) Pub. No.: US 2006/0145265 A1
(43) Pub. Date: Jul. 6, 2006

(54) CMOS semiconductor device

(76) Inventors: Yuri Masuoka, Kanagawa (JP); Naohiko Kimizuka, Kanagawa (JP); Kiyotaka Imai, Kanagawa (JP); Toshiyuki Iwamoto, Tokyo (JP)

Correspondence Address: YOUNG & THOMPSON, 745 SOUTH 23RD STREET, 2ND FLOOR, ARLINGTON, VA, 22202, US

(21) Appl. No.: 11/300,419

(22) Filed: Dec. 15, 2005

(30) Foreign Application Priority Data
Dec. 22, 2004 (JP) 2004-370413

(51) Int. Cl. H01L 29/94

(52) U.S. Cl. 257/369

(57) ABSTRACT

While forming an N-type MOSFET 118 and a P-type MOSFET 120 within regions operating using the same power supply voltage, thickness of a gate insulating film 106a of an N-type MOSFET 118 is made to be thicker than thickness of a gate insulating film 106b of a P-type MOSFET 120.

This application is based on Japanese patent application NO. 2004-370413, the content of which is incorporated hereinto by reference.

### BACKGROUND

1. Technical Field

The present invention relates to a CMOS semiconductor device equipped with an N-type MOSFET and P-type MOSFET.

2. Related Art

CMOS (Complementary Metal Oxide Semiconductor) semiconductor devices where N-type MOSFETs (Metal Oxide Semiconductor Field Effect Transistor) and P-type MOSFETs are formed on the same semiconductor substrate are widely employed as a result of their beneficial characteristics such as low power consumption and high-speed operation.

Film thickness of a gate insulating film ensuring insulation between a gate electrode and a semiconductor substrate is one parameter for deciding MOSFET characteristics. When physical film thickness of this gate insulating film is made thick, it is possible to suppress flow of leakage current from the gate electrode to the semiconductor substrate. However, when the thickness of the physical film thickness of the gate insulating film is made thick, because gate insulating film capacitance is small, there is a trade-off where, when the MOSFET goes on, the number of carriers induced directly below the gate falls and on current is also reduced.

Normally, an optimum gate insulating film thickness can be decided taking this trade-off into consideration in the design of the MOSFET.

Technology of the related art constituting devices for gate insulating film film thickness are disclosed in cited reference 1 and are described using FIG. 7. In the related art, of MOSFETS 10, 20 formed on the same semiconductor substrate 1, electrical film thickness of gate insulating film 22 of MOSFET 20 formed on a region HV operating at a high power supply voltage is made thicker than the electrical film thickness of a gate insulating film 12 of MOSFET 10 formed on a region LV operating at a lower power supply voltage than the region HV. A method of changing physical film thickness (the column “Problems to be resolved by the invention”) and a method for changing dielectric constant of a gate insulating film (first embodiment) are disclosed in Japanese Laid-open patent publication NO. 2003-100896 as methods for changing electrical film thickness.

With this configuration, it is possible to suppress leakage current at the MOSFET 20 formed at the region HV where the power supply voltage is high with a high voltage applied to a gate 24. Further, if the voltage applied to the gate electrode 24 is high, it is possible for sufficient carriers to be induced directly below the gate electrode 24 even if the gate insulating film capacitance is small, and reduction of the on current is therefore made difficult. On the other hand, reduction of on current can be prevented at MOSFET 10 formed on a region LV of a lower power supply voltage where a low voltage is applied to gate electrode 14 by making gate insulating film 12 thin.

### SUMMARY OF THE INVENTION

The inventor of this application has singled out the following problems with the semiconductor device of the technology of the related art.

In the related art, N-type MOSFETs and P-type MOSFETs formed within regions (for example, region LV of FIG. 7) operating at the same power supply voltage have gate insulating films of mutually the same thickness.

Typically, comparing N-type MOSFETs and P-type MOSFETs operating at the same power supply voltage, it is easier for leakage current to occur for the N-type MOSFET. When the physical film thickness of the gate insulating film is made thick in order to keep leakage current of the N-type MOSFET a prescribed value or less, performance of the P-type MOSFET for which on current was originally small is further deteriorated.

However, because suppression of leakage current of the N-type MOSFET is usually given priority, the physical film thickness of the gate insulating film is made thick, and use takes place with the performance of the P-type MOSFET being deteriorated due to reduction of the on current simply being accepted.

The semiconductor device of the present invention comprises an N-type MOSFET and a P-type MOSFET operating at the same power supply voltage, film thickness of a gate insulating film of an N-type MOSFET being thicker than film thickness of a gate insulating film of a P-type MOSFET.

As a result of this characteristic, it is possible to suppress leakage current using a thick gate insulating film for an N-type MOSFET where leakage current occurs more easily than for a P-type MOSFET, and it is possible to prevent reduction of on current by making a gate insulating film thin for a P-type MOSFET where it is more difficult for leakage current to occur than for the N-type MOSFET.

For example, the present invention is capable of providing a semiconductor device comprised of an N-type MOSFET and a P-type MOSFET operating using a same power supply voltage, with the N-type MOSFET having a first gate insulating film and the P-type MOSFET having a second gate insulating film. Here, film thickness of the first gate insulating film is thicker than film thickness of the second gate insulating film.

According to the present invention, it is possible to adopt a structure capable of suppressing leakage current of an N-type MOSFET and maximizing performance of a P-type MOSFET.

### BRIEF DESCRIPTION OF THE DRAWINGS

The above and other objects, advantages and features of the present invention will be more apparent from the following description taken in conjunction with the accompanying drawings, in which:

FIG. 1 is a view showing a first embodiment of the invention of this application;

FIG. 2A to 2c is a view showing a process for manufacturing the first embodiment of the invention of this application;

FIG. 3A to 3C is a view showing a further process for manufacturing the first embodiment of the invention of this application;

FIG. 4A to 4C is a view showing another process for manufacturing the first embodiment of the invention of this application;

FIGS. 5A and 5B is a view showing a second embodiment of this application;

FIG. 6 is a view showing a third embodiment of this application; and

FIG. 7 is a view illustrating technology of the related art.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The following is a description employing the drawings of preferred embodiments of the present invention. Elements of the configuration common to each drawing are given the same numerals and descriptions are omitted as appropriate. Further, in the following, the simple term “film thickness” is taken to mean “physical film thickness”.

### First Embodiment

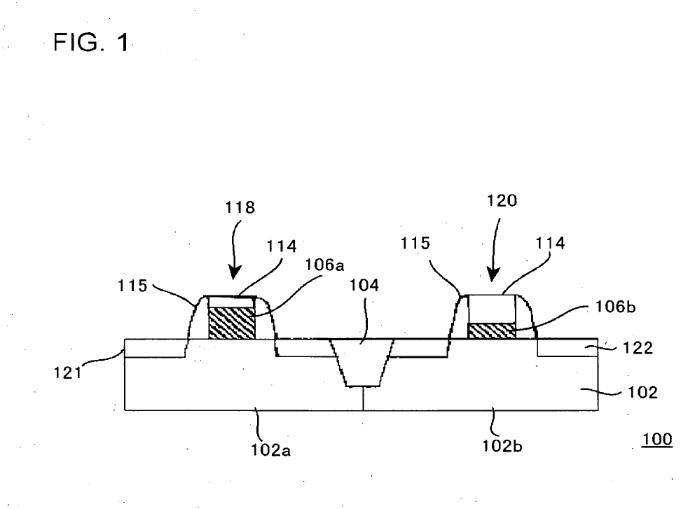

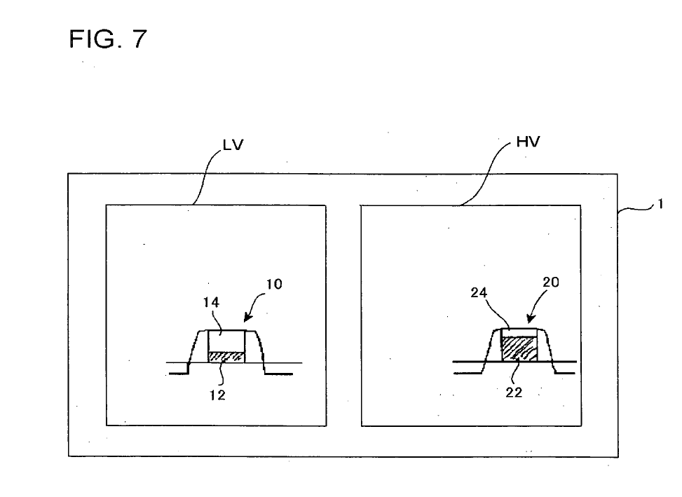

FIG. 1 is a cross-sectional view showing a configuration for a semiconductor device 100 of this embodiment. In this embodiment, the semiconductor device 100 is a CMOS (Complementary Metal Oxide Semiconductor) device including an N-type MOSFET 118 and P-type MOSFET 120, with both MOSFETs 118 and 120 operating using the same power supply voltage. Namely, the MOSFETs 118 and 120 are both formed on a region (for example, HV of FIG. 7) operating using a high power supply voltage or are both formed on a region (for example, LV of FIG. 7) operating using a lower power supply voltage. In particular, with a MOSFET formed on region LV operating using a low power supply voltage, the voltage applied to a gate electrode is also low, and there is a tendency for it to be difficult to induce carriers directly below the gate and for the on current to be small. It is therefore particularly demanded that the gate insulating film is thin in order to ensure the on current.

The effect of the invention of this application where it is possible to balance suppression of leakage current for the N-type MOSFET 118 and improvement of the on current of the P-type MOSFET 120 is therefore particularly striking for the region LV where power supply voltage is low.

The semiconductor device 100 includes a semiconductor substrate (in this embodiment, a silicon substrate) 102 provided with a P-well 102a of a P-type conductor and an N-well 102b of an N-type conductor, and an element isolation region 104 for isolating the P-well 102a and the N-well 102b. An N-type MOSFET 118 and a P-type MOSFET 120 are then formed at the P-well 102a and the N-well 102b, respectively.

A pair of N-type impurity diffusion regions 121 are formed at the P-well 102a, with a channel region (not shown) being formed in between. A gate constructed from a gate insulating film 106a comprised of a silicon oxide film, a gate electrode 114 constructed from a polycrystalline silicon film provided on the gate insulating film 106a, and a sidewall insulating film 115 is provided on the channel region. The gate electrode 114 of the N-type MOSFET 118 is doped with N-type impurity. The N-type MOSFET 118 is then constructed as a result.

Similarly, a pair of P-type impurity diffusion regions 122 are formed at the N-well 102b, with a channel region (not shown) being formed in between. A gate constructed from a gate insulating film 106b comprised of a silicon oxide film, a gate electrode 114 constructed from a polycrystalline silicon film provided on the gate insulating film 106b, and a sidewall insulating film 115 is provided on the channel region. The gate electrode 114 of the P-type MOSFET 120 is doped with P-type impurity, with the P-type MOSFET 120 then constructed as a result.

When the thicknesses of the gate insulating film 106a of the N-type MOSFET and the gate insulating film 106b of the P-type MOSFET are taken to be da, db respectively, then da>db.

The material of the gate insulating films 106a, 106b is not limited to a silicon oxide film and may be a silicon oxynitride film, silicon nitride film, or so-called high-dielectric constant film. The high-dielectric constant film can by constructed from a material including one or two or more elements selected from the group composed of, for example, Hf, Zr, Al and lanthanum family elements, and may also be taken to be an oxide film containing any of these elements or a silicate film etc.

Two examples of methods for manufacturing the semiconductor device 100 are described below.

(First Manufacturing Method of the First Embodiment)

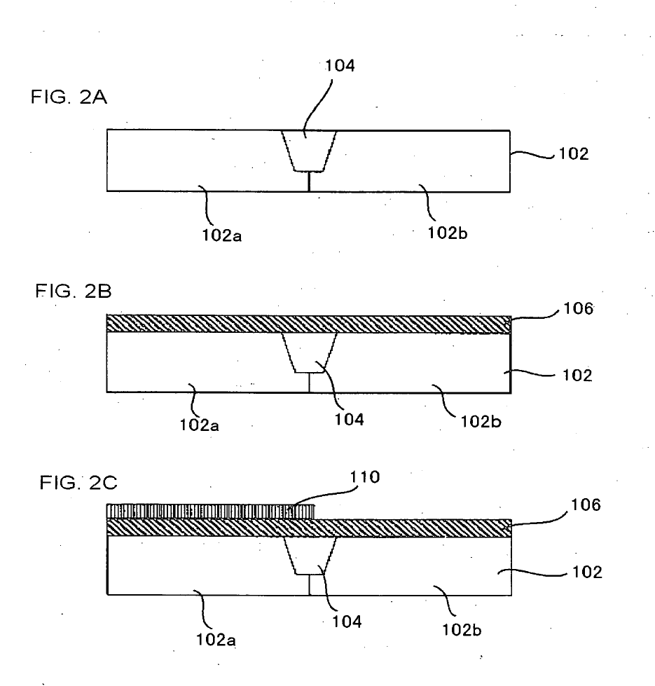

First, as shown in FIG. 2A, the element isolation region 104 is formed at the silicon substrate 102 using STI (Shallow Trench Isolation). Next, P-type impurities are ion-injected into one of the regions isolated by the element isolation region 104 so as to form the P-well 102a and N-type impurities are ion-injected into the other region so as to form the N-well 102b. The element isolation region 104 may also be formed using other publicly known methods such as, for example, LOCOS techniques, etc.

Continuing on, as shown in FIG. 2B, an insulating film 106 is formed on the surface of the silicon substrate 102. The insulating film 106 of a silicon oxide film can be formed by thermally oxidizing the surface of the silicon substrate 102. An insulating film 106 of a high-dielectric constant film can be formed using CVD or ALD (Atomic Layer Deposition) techniques. For example, in the event that hafnium silicate is selected as the material for the high-dielectric constant film, it is possible to form the insulating film 106 using an organic hafnium source gas, oxidizing gas and gas containing silicon. Oxygen may be used as the oxidizing gas and monosilane (SiH4) may be used as the gas containing silicon.

Continuing on, as shown in FIG. 2C, a photoresist 110 is formed on the P-well 102a. The photoresist 110 can be formed by applying resist onto the insulating film 106 and then performing exposure and development using a pattern-forming mask (not shown).

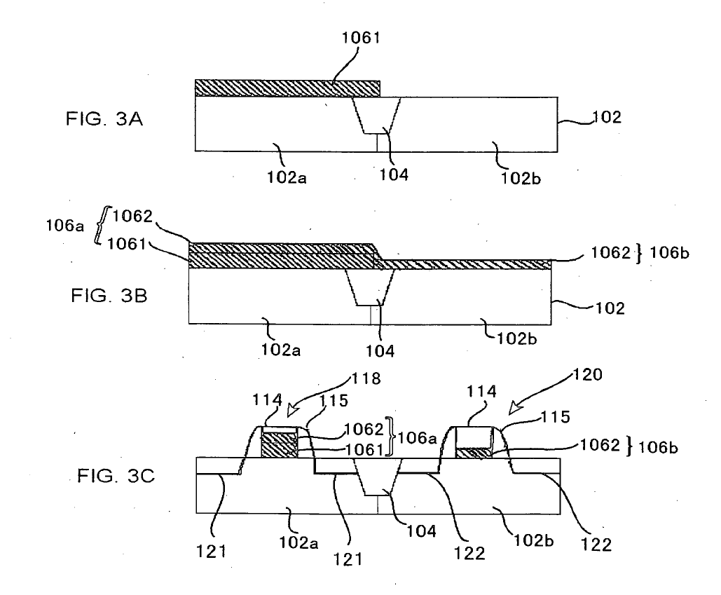

Continuing on, as shown in FIG. 3A, insulating film 106 on the N-well 102b is selectively removed by etching using the photoresist as a mask, with an insulating film 1061 remaining on the P-well 102a. The photoresist 110 is then peeled away and the surface of the insulating film 1061 is exposed.

As shown in FIG. 3B, an insulating film 1062 is formed on the insulating film 1061 and N-well 102b. The insulating film 1062 is formed using the same method as for the insulating film 106.

As a result of the above procedure, a gate insulating film 106a composed of the insulating films 1061 and 1062 is formed on the P-well 102a, and a gate insulating film 106b that is thinner than the gate insulating film 106a and is composed of the insulating film 1062 can be formed on the N-well 102b.

After this, gate electrode 114 and sidewall 115 are formed using the same procedure as for normal MOSFET manufacturing methods, with the semiconductor device 100 shown in FIG. 3C then being obtained by forming an N-type impurity region 121 in the P-well 102a and a P-type impurity region 122 in the N-well 102b as the source and drain.

As shown in FIG. 3C, the P-type MOSFET 120 has the gate insulating film 106b composed of the insulating film 1062. On the other hand, the N-type MOSFET 118 has the gate insulating film 106a composed of the insulating films 1061 and 1062. The gate insulating film 106a is therefore thicker than the gate insulating film 106b only by the portion of the insulating film 1061.

(Second Manufacturing Method of the First Embodiment)

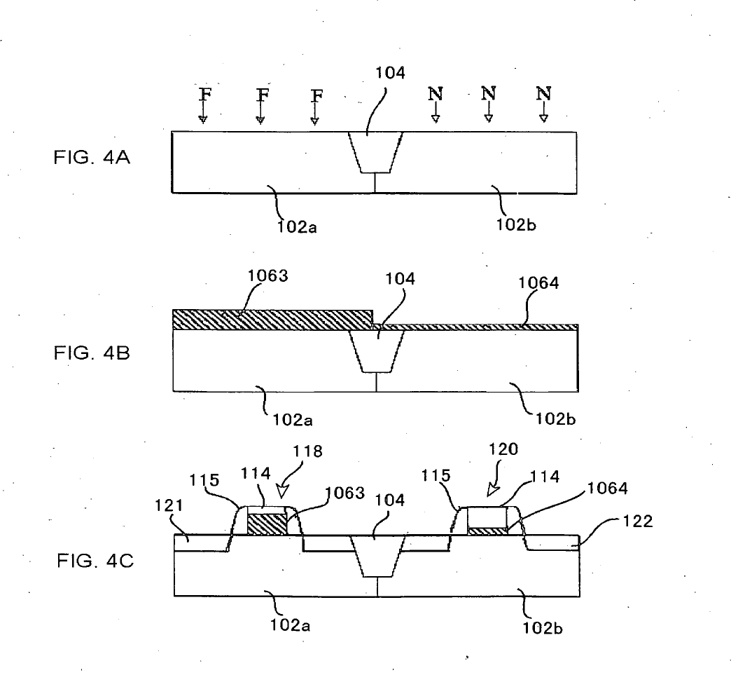

A description is now given with reference to FIG. 4 of a further method for manufacturing the semiconductor device 100.

First, the silicon substrate 102 provided with the element isolation region 104, P-well 102a and N-well 102b is prepared.

Next, as shown in FIG. 4, fluorine is injected into the P-well 102a and nitrogen is injected into the N-well 102b. Injection of fluorine is carried out after masking the N-well 102b with photoresist, etc. On the other hand, injection of nitrogen is carried out after similarly masking the P-well 102a.

After this, as shown in FIG. 4B, the surface of the silicon substrate 102 is subjected to thermal oxidation so as to form an insulating film 1063 constituted by a thermally oxidized film on the P-well 102a and form an insulating film 1064 constituted by a thermally oxidized film on the N-well. Thermal oxidation is promoted at the surface of the silicon substrate 102 injected with fluorine. On the other hand, thermal oxidation is suppressed at the surface of the silicon substrate 102 injected with nitrogen. The film thickness of the insulating film 1063 is therefore thicker than the film thickness of the insulating film 1064.

Next, as shown in FIG. 4C, gate electrode 114 and sidewall 115 are formed using the same procedure as for normal MOSFET manufacturing methods, with the semiconductor device 100 then being obtained by forming an N-type impurity region 121 in the P-well 102a and a P-type impurity region 122 in the N-well 102b as the source and drain.

As shown in FIG. 4C, the P-type MOSFET 120 has a gate insulating film composed of insulating film 1064. On the other hand, the N-type MOSFET 118 has a gate insulating film composed of insulating film 1063 of a thicker film thickness than the insulating film 1064.

It is also possible to obtain the same structure in the event of injecting just one of fluorine or nitrogen.

### Second Embodiment

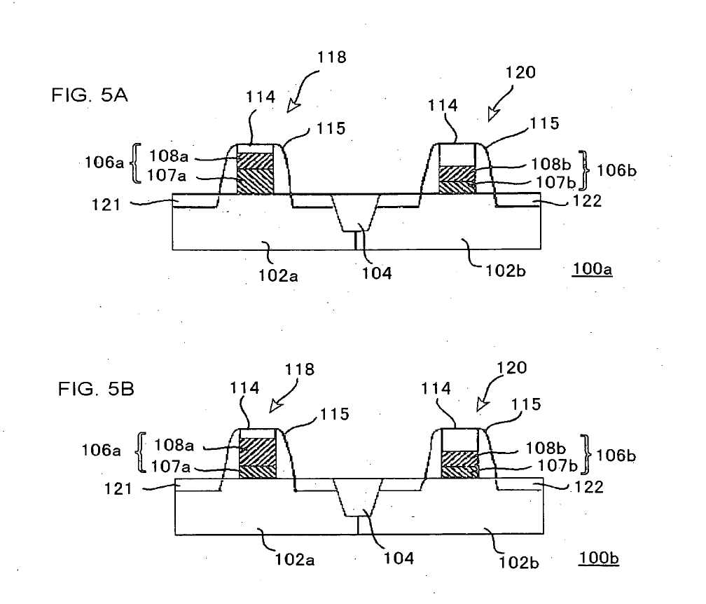

A second embodiment of the present invention is now described using FIG. 5.

The second embodiment differs from the first embodiment in that the gate insulating film 106a has a structure where a silicon oxide film (first insulating film) 107a and a high-dielectric constant film (second insulating film) of a higher dielectric constant than the silicon oxide film 107a are stacked, and the gate insulating film 106b has a structure where a silicon oxide film (third insulating film) 107b and a high-dielectric constant film (fourth insulating film) 108b of a higher dielectric constant than the silicon oxide film 107b are stacked. When a high-dielectric constant film is used, it is possible to make physical film thickness thick and electrical film thickness thin.

Here, the high-dielectric constant films 108a and 108b may be high-dielectric constant films including elements selected from the group of Hf, Zr, Al and lanthanum family elements.

With the semiconductor device 100a shown in FIG. 5A, film thickness of the silicon oxide film 107a of the N-type MOSFET 118 is thicker than the film thickness of the silicon oxide film 107b of the P-type MOSFET 120. The high-dielectric constant film 108a of the N-type MOSFET 118 and the high-dielectric constant film 108b of the P-type MOSFET 120 have substantially the same film thickness.

On the other hand, with the semiconductor device 100b shown in FIG. 5B, the silicon oxide film 107a and the silicon oxide film 107b have substantially the same film thickness, while the film thickness of the high-dielectric constant film 108a is thicker than the film thickness of the high-dielectric constant film 108b.

Because the film thicknesses of the silicon oxide films 107a, 107b mutually change, the same method can be used for the first manufacturing method or the second manufacturing method of the first embodiment.

Further, because the film thicknesses of the high-dielectric constant films 108a, 108b mutually change, the same method as for the first manufacturing method of the first embodiment can be used.

It is not necessary to etch the high-dielectric constant films in order to obtain the structure for the semiconductor device 100a. It is difficult to make selectivity for the high-dielectric constant film and the silicon oxide film (or silicon nitride film etc.) large, the silicon oxide film (or silicon nitride film etc.) remains, and elimination of only the high-dielectric constant film is difficult. The structure shown for 100a is therefore easily manufactured compared to the structure shown in 100b.

On the other hand, the structure for the semiconductor device 100b is such that the physical film thickness of the high-dielectric constant film 108a of the N-type MOSFET 118 is thick compared with the semiconductor device 100a. The physical film thickness of the gate insulating film 106a is therefore made thick and it is possible to keep the electrical film thickness thin. As a result, performance of the N-type MOSFET 118 of the semiconductor device 100b is higher than performance of the N-type MOSFET 118 of the semiconductor device 100a.

### Third Embodiment

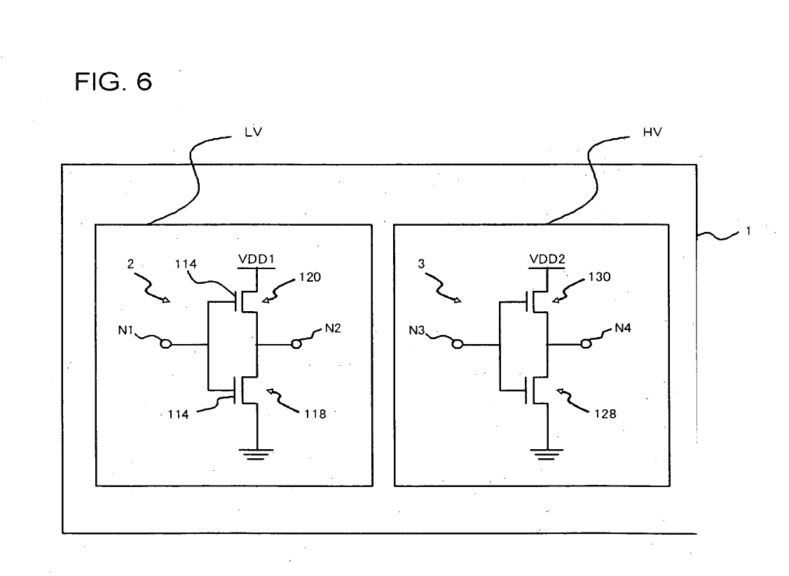

A description of a third embodiment of the present invention is given using FIG. 6.

In this embodiment, a region LV operating using a first power supply voltage VDD1 and a region HV operating using a second power supply voltage VDD2 are provided on a semiconductor substrate 1. Here, the first power supply voltage VDD1 is lower than the second power supply voltage VDD2.

The N-type MOSFET 118 and the P-type MOSFET 120 are formed within the region LV, and a single inverter 2 having an input node N1 and an output node N2 is constructed from the MOSFETS 118, 120. Gate electrode 114 of the N-type MOSFET 118 and gate electrode 114 of the P-type MOSFET 120 are both connected to the input node N1 of the inverter 2. Therefore, when a signal is inputted to the input node N1, the same voltage is applied to the gate electrode 114 of the N-type MOSFET 118 and the gate electrode 114 of the P-type MOSFET 120. The voltage of the input signal is usually substantially equal to operating voltage VDD1 of the region LV.

In this embodiment, as with the first embodiment, film thickness of the gate insulating film of the N-type MOSFET 118 is thicker than the film thickness of the gate insulating film of the P-type MOSFET 120. Further, the same material, configuration, and film thickness relationship as for the gate insulating film of the second embodiment can be adopted.

Further, an N-type MOSFET 128 and a P-type MOSFET 130 are provided within the region HV and a single inverter 3 having an input node N3 and an output node N4 can be constructed using the MOSFETS 128, 130.

The film thickness dc of the gate insulating film 106c of the N-type MOSFET 128 may be the same as the film thickness dd of the gate insulating film 106d of the P-type MOSFET 130 or the film thickness dc may be thicker than the film thickness dd as in the first and second embodiments. Moreover, the gate insulating films 106c and 106d may also have a structure where the silicon oxide film and the high-dielectric constant film are stacked as in the second embodiment.

Further, the film thicknesses da, db, dc, dd satisfy at least the size relationships of da<dc and db<dd.

It is apparent that the present invention is not limited to the above embodiments, that may be modified and changed without departing from the scope and spirit of the invention.

For example, in the second embodiment, the first insulating film of the gate oxide film 106a and the third insulating film of the gate oxide film 106b are silicon oxide films but this is by no means limiting, and silicon oxynitride films or silicon nitride films are also possible.

What is claimed is:

1. A semiconductor device comprising:
an N-type MOSFET and a P-type MOSFET operating using a same power supply voltage;
said N-type MOSFET having a first gate insulating film; and
said P-type MOSFET having a second gate insulating film, wherein film thickness of said first gate insulating film is thicker than film thickness of said second gate insulating film.

2. The semiconductor device as claimed in claim 1, said first gate insulating film being a film formed by stacking a first insulating film and a second insulating film; and
said second gate insulating film being a film formed by stacking a third insulating film and a fourth insulating film,
wherein a dielectric constant of the first insulating film is lower than a dielectric constant of the second insulating film; and
a dielectric constant of the third insulating film is lower than a dielectric constant of the fourth insulating film.

3. The semiconductor device as claimed in claim 2, wherein film thickness of said first insulating film is thicker than film thickness of said third insulating film.

4. The semiconductor device as claimed in claim 3, wherein film thickness of said second insulating film is substantially the same as film thickness of said fourth insulating film.

5. The semiconductor device as claimed in claim 2, wherein film thickness of said second insulating film is thicker than film thickness of said fourth insulating film.

6. The semiconductor device as claimed in claim 5, wherein film thickness of said first insulating film is substantially the same as film thickness of said third insulating film.

7. The semiconductor storage device as claimed in claim 1, wherein said first gate insulating film and said second gate insulating film are composed of a material selected from the group consisting of silicon oxide film, silicon oxynitride film, and silicon nitride film.

8. The semiconductor storage device as claimed in claim 1, wherein said first gate insulating film and said second gate insulating film are high-dielectric constant films containing elements selected from the group consisting of Hf, Zr, Al and lanthanum family elements.

9. The semiconductor storage device as claimed in claim 2, wherein said first insulating film and said third insulating film are composed of a material selected from the group consisting of silicon oxide film, silicon oxynitride film, and silicon nitride film.

10. The semiconductor storage device as claimed in claim 2, wherein said second insulating film and said fourth insulating film are high-dielectric constant films containing elements selected from the group consisting of Hf, Zr, Al and lanthanum family elements.

11. The semiconductor storage device as claimed in claim 1, wherein said N-type MOSFET and said P-type MOSFET constitute a single inverter.

12. The semiconductor device as claimed in claim 1, further comprising:
a first region operating using a first power supply voltage; and
a second region operating using a second power supply voltage higher than said first power supply voltage,
wherein said N-type MOSFET and said P-type MOSFET are both formed within said first region.

13. The semiconductor device as claimed in claim 12, wherein a plurality of MOSFETs are formed within said second region, and film thicknesses of gate insulating films possessed by said plurality of MOSFETs are substantially the same.
